(19) United States
(12) Patent Application Publication
(10) Pub. No.: US 2024/0169108 A1
(43) Pub. Date: May 23, 2024

(54) NETWORK SENSOR DEPLOYMENT FOR UTILITIES INFRASTRUCTURE

(71) Applicant: BRITISH TELECOMMUNICATIONS PUBLIC LIMITED COMPANY, London (GB)

(72) Inventors: Carla DI CAIRANO-GILFEDDER, London (GB); Anthony MICK, Alistair CONWAY, London (GB); Alan GOULD, London (GB)

(21) Appl. No.: 18/551,495

(22) PCT Filed: Mar. 10, 2022
(86) PCT No.: PCT/EP2022/056227

§ 371 Date: Sep. 20, 2023

(30) Foreign Application Priority Data
Mar. 22, 2021 (GB) 2103930.0

(51) Int. Cl. G06F 30/18; G06F 30/27

(52) U.S. Cl. CPC G06F 30/18; G06F 30/27

(57) ABSTRACT

A computer implemented method of deploying a network connected sensor for sensing characteristics of a plurality of infrastructure components in a transmission network for a utility service is disclosed.

### PRIORITY CLAIM

The present application is a National Phase entry of PCT Application No. PCT/EP2022/056227, filed Mar. 10, 2022, which claims priority from GB Patent Application No. 2103930.0, filed Mar. 22, 2021, each of which is hereby fully incorporated herein by reference.

### TECHNICAL FIELD

The present disclosure relates to the deployment of network connected sensors for monitoring infrastructure components in a deployed utilities infrastructure.

### BACKGROUND

Utility service providers have transmission networks for the transport, provision, communication or conveyance of a utility such as power (including electricity), gas (including natural gas), liquid (including water), sewage and communications facilities (including fixed-line and/or mobile telephony and network connections such as broadband services). Transmission networks are comprised of network infrastructure including means and mechanisms for the transmission of the utility. Such infrastructure includes infrastructure components that can be categorized into component types. One categorization can include, for example, a nature of a location, installation or fitment of an infrastructure component such as: above-ground; under-ground; or affixed to another element such as a building or the like. Other or enhanced categorizations of infrastructure component types can include types according to a nature of a component such as a conduit, transmission wire, emitter or receiver or the like. Infrastructure components can include, for example, a duct, conduit, pipe, cable, pole, pylon, tower, and other transmission network infrastructure components as will be apparent to those skilled in the art.

Utility service providers are increasingly subject to infrastructure sharing obligations which require the provision of access to physical infrastructure such including infrastructure components to third parties. For example: ducts and poles can be shared; power can be shared; and infrastructure site access can be shared. These obligations on infrastructure owners introduces an additional requirement for effective infrastructure design, deployment and maintenance.

Accordingly, utility service providers require accurate and up-to-date records of the nature, state and arrangement of utility infrastructure components, and need to ensure the state of utilities infrastructure is acceptable.

### SUMMARY

According to a first aspect of the present disclosure, there is provided a computer implemented method of deploying a network connected sensor for sensing characteristics of a plurality of infrastructure components in a transmission network for a utility service, the method comprising: training a classifier to indicate the suitability of a location of an infrastructure component for deployment of the network connected sensor, the classifier operable on an input vector for an infrastructure component at a location including indications of: a measure of an extent of coverage of infrastructure components in the transmission network by a sensor deployed at the location; a measure of relative performance of infrastructure components within the extent of coverage of a sensor deployed at the location; and an indication of suitability for network communication by a sensor deployed at the location, wherein the classifier is trained based on supervised training data; receiving an input vector for each of a plurality of infrastructure components; applying the classifier to the input vector for each of the plurality of infrastructure components to identify an infrastructure component being most suitable for situating the network connected sensor; and triggering the deployment of the network connected sensor at a location of the identified infrastructure component.

In some embodiments, the measure of an extent of coverage by a sensor deployed at a location includes a measure of a number of infrastructure components that can be sensed by a sensor deployed at the location.

In some embodiments, the measure of a relative performance of infrastructure components includes a normalized measure of one or more of: reliability; operability; faults; and uptime for the infrastructure components.

In some embodiments, the indication of suitability for network communication by a sensor deployed at a location is determined based on one or more of: a distance of the location to a nearest network access point; a record of obstacles located between the location and a nearest network access point; and a record of network access facilities at the location.

In some embodiments, the infrastructure component being most suitable for situating the network connected sensor is determined based on a measure of a degree of membership of the infrastructure component with a class of the classifier indicating suitability of a location of the infrastructure component.

According to a second aspect of the present disclosure, there is a provided a computer system including a processor and memory storing computer program code for performing the method set out above.

According to a third aspect of the present disclosure, there is a provided a computer system including a processor and memory storing computer program code for performing the method set out above.

### BRIEF DESCRIPTION OF THE DRAWINGS

Embodiments of the present disclosure will now be described, by way of example only, with reference to the accompanying drawings, in which:

FIG. 1 is a block diagram a computer system suitable for the operation of embodiments of the present disclosure.

FIG. 2 is a component diagram of an arrangement to deploy a network connected sensor for sensing characteristics of a plurality of infrastructure components in a transmission network for a utility service in accordance with an embodiment of the present disclosure.

FIG. 3 is a flowchart of a method to deploy a network connected sensor for sensing characteristics of a plurality of infrastructure components in a transmission network for a utility service in accordance with an embodiment of the present disclosure.

### DETAILED DESCRIPTION

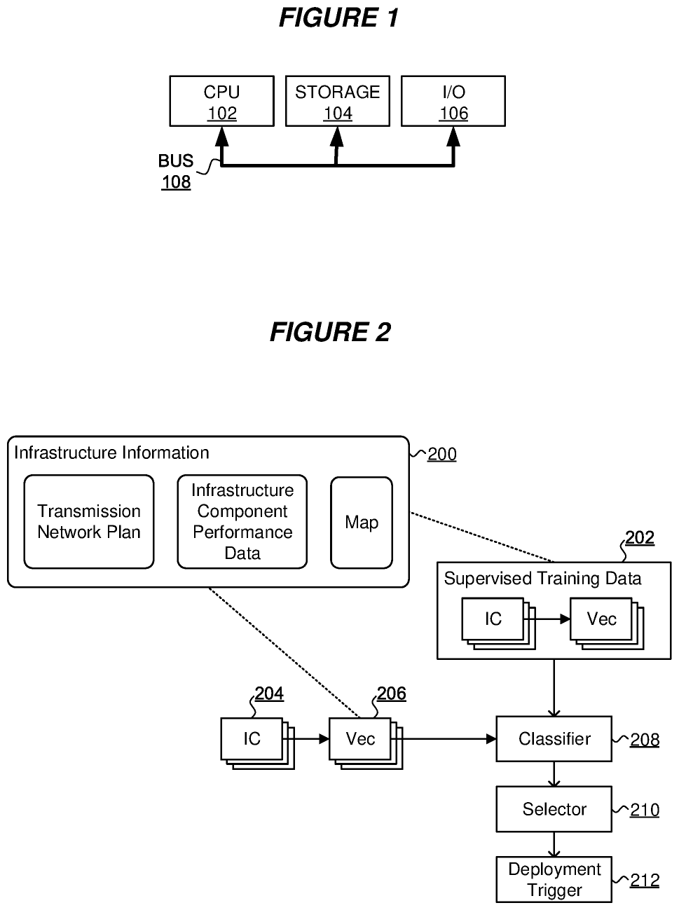

FIG. 1 is a block diagram of a computer system suitable for the operation of embodiments of the present disclosure. A central processor unit (CPU) 102 is communicatively connected to a storage 104 and an input/output (I/O) interface 106 via a data bus 108. The storage 104 can be any read/write storage device such as a random-access memory (RAM) or a non-volatile storage device. An example of a non-volatile storage device includes a disk or tape storage device. The I/O interface 106 is an interface to devices for the input or output of data, or for both input and output of data. Examples of I/O devices connectable to I/O interface 106 include a keyboard, a mouse, a display (such as a monitor) and a network connection.

FIG. 2 is a component diagram of an arrangement to deploy a network connected sensor for sensing characteristics of a plurality of infrastructure components in a transmission network for a utility service in accordance with an embodiment of the present disclosure. Embodiments of the present disclosure determine a location of an infrastructure component most suitable for deployment of a network connected sensor for sensing characteristics of multiple infrastructure components. The infrastructure components 204 in the transmission network are susceptible to sensing by a sensor such as, inter alia: a light detection and ranging (LIDAR) sensor; an image sensor for generating an image of at least part of the infrastructure component; a temperature sensor; a radar sensor; a ground-penetrating radar sensor; an electromagnetic sensor; and electro-optical sensor; and a sound sensor. The sensor is network connected such as an internet-of-things (JOT) sensor or the like and is to be deployed collocated with an infrastructure component such as by being located immediately adjacent the component, mounted on, with or adjacent the component. Thus, the sensor is adapted to sense at least a subset of the characteristics of the infrastructure component with which it is collocated and one or more other infrastructure components local to the collocated infrastructure component.

The sensor thus generates sensor data as sensor output such as images from an image sensor, audio records from a sound sensor, LIDAR data from a LIDAR sensor and so on. Additionally, the sensor is network-connected such that the sensor is operable to communicate via a wired or wireless network such as a cellular, wide-area or wifi network. Thus, when deployed, the sensor is operable to provide sensed data for a plurality of infrastructure components via its network connection.

A classifier 208 is provided as a machine learning algorithm suitable for training by supervised training data 202 to indicate the suitability of a location of an infrastructure component for deployment of a network connected sensor. The indication is provided by the classifier by way of classification of data for a plurality of candidate infrastructure components 204 such as classes indicating suitability and unsuitability of a candidate infrastructure component. Furthermore, a determination of a most suitable infrastructure component can be made based on the output of the classifier for a plurality of candidate infrastructure components either alone or in conjunction with other differentiating data for classified suitable infrastructure components. For example, an infrastructure component being most suitable for situating the sensor can be determined based on a measure of a degree of membership of the infrastructure component with a class of the classifier indicating suitability of a location of the infrastructure component. Such a degree of membership can be determined, for example, by reference to a classification score by the classifier 208, or using other suitable means as will be apparent to those skilled in the art.

The classifier is trained based on supervised training data 202 using, for example, a backpropagation training method or other suitable mechanism as will be apparent to those skilled in the art. The training data 202 is constituted as an input vector for each training example being labelled by an indication of its suitability for location of a sensor by way of supervision for the classifier 208. The input vector for the classifier 208 relates to a single infrastructure component having a location and includes indications of each of: a measure of an extent of coverage of infrastructure components in the transmission network by a sensor deployed at the location; a measure of relative performance of infrastructure components within the extent of coverage of a sensor deployed at the location; and an indication of suitability for network communication by a sensor deployed at the location.

For an infrastructure component training example in respect of an infrastructure component at a particular location, the measure of an extent of coverage of infrastructure components in the transmission network by a sensor deployed at the location can, for example, include a measure of a number of infrastructure components that can be sensed by a sensor deployed at the location. For example, such information can be inferred or determined from infrastructure information 200 such as a transmission network plan that identifies relative locations of infrastructure components in the transmission network, with or without a geographic map indicating features and relative locations.

Further, for an infrastructure component training example in respect of an infrastructure component at a particular location, the measure of relative performance of infrastructure components within the extent of coverage of a sensor deployed at the location can be determined based on infrastructure component performance data, such as can be provided by infrastructure information 200. In some embodiments, relative performance information includes a normalized measure of one or more of: reliability; operability; faults; and uptime for the infrastructure components that can be sensed by the sensor if located at the location of the infrastructure component of the training example.

Further, for an infrastructure component training example in respect of an infrastructure component at a particular location, and an indication of suitability for network communication by a sensor deployed at the location can be determined based on, for example, inter alia: data indicative of one or more wired network connections available at the location; a distance of the location to a nearest wires or wireless network access point, such as may be determined using the transmission network plan; a record of obstacles located between the location and a nearest network access point, such as may be determined using the map; and a record of network access facilities at the location.

In some embodiments, the indications provided for the vector of a training data example are provided using an encoding scheme such as a one-hot encoding as will be familiar to those skilled in the art. Such encoding is particularly suited for training and executing a classifier 208.

Once trained, the classifier 208 is operable based on an input vector 206 for each of a plurality of candidate infrastructure components 204 to classify the infrastructure components 204 on which basis to determine a most suitable infrastructure component for location of the sensor. The vector 206 for each candidate infrastructure component 204 is constituted in the same manner as the training data vectors based on, for example, the infrastructure information 200 as described above. Thus, in use, the classifier is applied to each input vector 206 to determine infrastructure components classified for suitability, with differentiation of suitable components being made by a selector component 210 such as a hardware, software, firmware or combination component arranged to identify a most suitable infrastructure component based on the classification by the classifier 208 as previously described. Subsequently, a deployment trigger component 212 as a hardware, software, firmware or combination component is operable to trigger the deployment of the network connected sensor at a location of the identified most suitable infrastructure component.

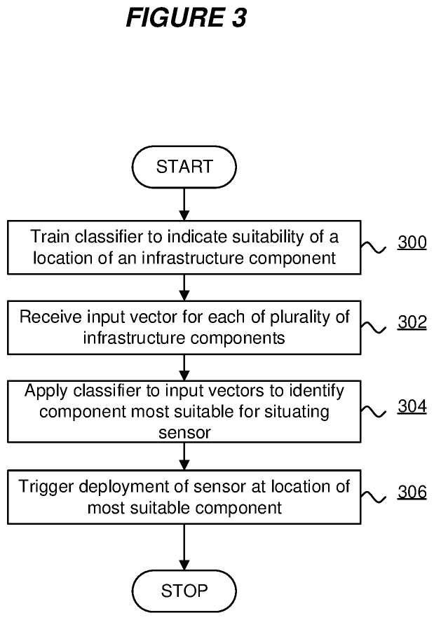

FIG. 3 is a flowchart of a method to deploy a network connected sensor for sensing characteristics of a plurality of infrastructure components in a transmission network for a utility service in accordance with an embodiment of the present disclosure. Initially, at 300, the method trains the classifier 208 to indicate suitability of a location of an infrastructure component. At 302 the method receives an input vector 206 for each of a plurality of candidate infrastructure components 204 and the input vectors are classified at 304 by the trained classifier 208 to identify an infrastructure component having a most suitable location. At 306 the method triggers deployment of the network connected sensor at a location of the most suitable infrastructure component for monitoring infrastructure components.

Insofar as embodiments of the disclosure described are implementable, at least in part, using a software-controlled programmable processing device, such as a microprocessor, digital signal processor or other processing device, data processing apparatus or system, it will be appreciated that a computer program for configuring a programmable device, apparatus or system to implement the foregoing described methods is envisaged as an aspect of the present disclosure. The computer program may be embodied as source code or undergo compilation for implementation on a processing device, apparatus or system or may be embodied as object code, for example.

Suitably, the computer program is stored on a carrier medium in machine or device readable form, for example in solid-state memory, magnetic memory such as disk or tape, optically or magneto-optically readable memory such as compact disk or digital versatile disk etc., and the processing device utilizes the program or a part thereof to configure it for operation. The computer program may be supplied from a remote source embodied in a communications medium such as an electronic signal, radio frequency carrier wave or optical carrier wave. Such carrier media are also envisaged as aspects of the present disclosure.

It will be understood by those skilled in the art that, although the present disclosure has been described in relation to the above described example embodiments, the disclosure is not limited thereto and that there are many possible variations and modifications which fall within the scope of the claims.

The scope of the present disclosure includes any novel features or combination of features disclosed herein. The applicant hereby gives notice that new claims may be formulated to such features or combination of features during prosecution of this application or of any such further applications derived therefrom. In particular, with reference to the appended claims, features from dependent claims may be combined with those of the independent claims and features from respective independent claims may be combined in any appropriate manner and not merely in the specific combinations enumerated in the claims.

1. A computer implemented method of deploying a network connected sensor for sensing characteristics of a plurality of infrastructure components in a transmission network for a utility service, the method comprising:
training a classifier to indicate a suitability of a location of an infrastructure component for deployment of the network connected sensor, the classifier operable on an input vector for the infrastructure component at the location including indications of: a measure of an extent of coverage of infrastructure components in the transmission network by a sensor deployed at the location; a measure of relative performance of infrastructure components within an extent of coverage of a sensor deployed at the location; and an indication of suitability for network communication by a sensor deployed at the location, wherein the classifier is trained based on supervised training data;
receiving an input vector for each of a plurality of infrastructure components;
applying the classifier to the input vector for each of the plurality of infrastructure components to identify an infrastructure component being most suitable for situating the network connected sensor; and
triggering deployment of the network connected sensor at a location of the identified infrastructure component.

2. The method of claim 1, wherein the measure of the extent of coverage by the sensor deployed at the location includes a measure of a number of infrastructure components that can be sensed by a sensor deployed at the location.

3. The method of claim 1, wherein the measure of the relative performance of infrastructure components includes a normalized measure of one or more of: reliability; operability; faults; or uptime for the infrastructure components.

4. The method of claim 1, wherein the indication of suitability for network communication by the sensor deployed at the location is determined based on one or more of: a distance of the location to a nearest network access point; a record of obstacles located between the location and a nearest network access point; or a record of network access facilities at the location.

5. The method of claim 1, wherein the infrastructure component being most suitable for situating the network connected sensor is determined based on a measure of a degree of membership of the infrastructure component with a class of the classifier indicating suitability of the location of the infrastructure component.

6. A computer system comprising a processor and memory storing computer program code for performing the method of claim 1.

7. A non-transitory computer-readable storage medium comprising computer program code to, when loaded into a computer system and executed thereon, cause the computer system to perform the method as claimed in claim 1.
